(19) United States
(12) Patent Application Publication
(10) Pub. No.: US 2015/0081237 A1
(43) Pub. Date: Mar. 19, 2015

(54) DATA DRIVEN/PHYSICAL HYBRID MODEL FOR SOC DETERMINATION IN LITHIUM BATTERIES

(71) Applicant: Seeo, Inc, Hayward, CA (US)

(72) Inventors: Changqing Ye, Carlsbad, CA (US); Peter Paris, San Diego, CA (US); Larry Deal, Shelby Township, MI (US); Scott Allen Mullin, San Leandro, CA (US); Mohit Singh, Berkeley, CA (US)

(21) Appl. No.: 14/032,160

(22) Filed: Sep. 19, 2013

(51) Int. Cl. G01R 31/36

(52) U.S. Cl. CPC G01R 31/3651
USPC 702/63

(57) ABSTRACT

A hybrid model to determine state-of-charge for lithium batteries includes both a physical model and an empirical or data-driven model. The physical model is an electrochemical model, based on the battery materials properties and structure and describes dynamic electrochemical reactions. The empirical model uses coulomb counting and a relaxation filter, plus a Kalman filter for adaptive compensation of the system parameters. In some SOC regimes, one model is strongly favored over the other. In some SOC regions, a weighted combination of the two models is used.

### STATEMENT OF GOVERNMENT SUPPORT

The invention described and claimed herein was made in part utilizing funds supplied by the U.S. Department of Energy under Contract No. DE-0E0000223. The Government has certain rights in this invention.

### BACKGROUND OF THE INVENTION

This invention relates generally to methods for determining state of charge for secondary batteries, and, more specifically, to combining a physical and an empirical model together to increase the accuracy of state-of-charge determination.

State of charge (SOC) is equivalent to a fuel gauge measurement for the battery pack in a battery electric vehicle (BEV), hybrid vehicle (HEV), or plug-in hybrid electric vehicle (PHEV). SOC is usually expressed as a percentage of full charge (e.g., 0%=empty; 100%=full). An alternate form of the same measurement is the depth of discharge (DoD), the inverse of SOC (e.g., 100%=empty; 0%=full). SOC is normally used when discussing the current state of a battery in use, while DoD is most often used when discussing the capacity utilization of a cell during performance rating or cycle life testing.

State-of-charge (SOC) and state-of-health (SOH) are important parameters for monitoring and controlling battery cells, but they can be difficult to determine in many cases. SOH is typically estimated by tracking a cell's accessible capacity. It is important to note that only fully-charged or fully-discharged cells have well-defined SOCs (100% and 0%, respectively).

For battery chemistries where the open-circuit voltage (OCV) decreases continuously during discharge, there is a reasonable correlation between the open-circuit voltage and the SOC. When a cell is either charging or discharging (that is, under operation instead of in an open-circuit condition), the passing of current causes a deviation from the open-circuit voltage that depends on the sign and magnitude of the current. Charging increases the voltage above the cell's OCV and discharging decreases the voltage below the cell's OCV. When current is removed and a cell is allowed to relax, the cell voltage can return to the OCV. Deviations from OCV under load are caused by several phenomena, including electrochemical effects such as electrolyte polarization and interfacial polarization. In the simplest operation scenarios, the OCV can be determined once a sufficient period of relaxation time has passed. In chemistries where the OCV changes significantly with SOC and in which the deviations from OCV under load conditions are relatively small, voltages under load can be used as a close proxy for the OCV. Thus, the voltage along with the amount of current passed into and out of the cell can be used to make an estimate of the SOC. For such battery chemistries, these estimates are often good enough for most purposes.

But for some other battery chemistries, the open-circuit voltage does not decrease continuously during discharge. For example, in a cell with a lithium metal anode and a LiFePO₄ cathode, the open-circuit voltage decreases at the very beginning of discharge and then remains stable throughout most of the discharge until it finally drops at the end. As the cell continues to discharge, the SOC decreases whereas the open-circuit voltage remains nearly constant. This relatively flat open-circuit voltage curve is not useful in trying to determine the SOC of such a cell.

Well-known data-driven (Kalman filter)-based battery models are often used to determine a battery's SOC from repeated terminal voltage measurements. This has the advantages of relatively simple implementation, adaptive self-correction, and high accuracy, all with limited computation resources. But this kind of data-driven model does not work very well in ranges where the OCV vs. SOC curve is flat.

Additional factors that can undermine SOC determination from voltage monitoring may include measurement uncertainty and cell polarization.

Another method, known as current accounting or Coulomb counting, calculates the SOC by measuring the battery current and integrating it over time. Problems with this method include long-term drift, lack of a reference point, and, uncertainties about a cell's total accessible capacity (which changes as the cell ages) and operation history.

SOH determination is similarly convoluted—accurate capacity determination is difficult in dynamic usage scenarios due to errors in Coulomb counting. These problems are particularly compounded in lithium-polymer cells in which transport limitations give rise to significant cell polarization, obscuring voltage end-point determination under load.

Some methods of SOC determination involve fitting complicated resistor-capacitor (RC) circuit models to a priori tests in order to model dynamic cell behavior. However, those methods are very complicated, computationally intensive, and are indirect, all of which can contribute to errors and cost. Moreover, such methods are set up in advance, making them not very useful in determining real-time status indicators.

What is needed is an accurate and reliable method to determine the SOC for rechargeable batteries over their entire charge range.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1 is a plot of cell voltage as a function of depth of discharge for an exemplary battery cell.

FIG. 2 is a diagram that shows the steps in a method of determining SOC according to an embodiment of the invention.

FIG. 3 is a plot of voltage as a function of SOC that was generated by allowing a cell to relax to its equilibrium value after discharging to various SOC values.

FIG. 4 is a plot of voltage and current as a function of time and shows changes that occur with contant current discharges and rest steps at each 10% decrease in cell capacity.

FIG. 5 is a plot of open-circuit voltage as a function of log time that was generated using data extracted from FIG. 4.

FIG. 6 is a plot that shows f(Γ) as a function of log F at various SOCs according to Equation 2 (shown below) that was generated using data extracted from FIG. 5.

FIG. 7 is a plot that shows f(Γ)-weighted-average values of F as a function of SOC that was generated using data extracted from FIG. 6.

FIG. 8 is a plot that shows values of time constants τ₁ and τ₂, each as a function of SOC, for the first 10 seconds of the curves shown in the resting case of FIG. 5.

FIG. 9 is a plot of voltage and current as a function of time and shows changes that occur during a current discharge that has periodic high-current discharge pulses at each 10% decrease in cell capacity.

FIG. 10 is a plot that shows values of time constants τ₁ and τ₂, each as a function of SOC, for the first 10 seconds of the curves shown in the non-resting case in FIG. 8.

FIG. 11 is a plot of open-circuit voltage as a function of log time during various rest stages, extracted from cycling data for a cell over the course of over 450 cycles.

FIG. 12 is a plot that shows time constants as extracted from the curves in FIG. 9.

FIG. 13 shows a computer system that is programmed or otherwise configured to determine the state of charge of a battery.

### SUMMARY

A method of determining state of charge (SOC) for a rechargeable battery cell at various times tₙ throughout the discharge portion the cell's cycle is disclosed. The method includes the steps of:
a. fully charging a battery cell comprising lithium metal as an anode, lithium iron phosphate as a cathode, and a polymer electrolyte as a separator so that SOC is 100%;
b. discharging the cell over a period of time tₓ while also recording in a memory location voltage(tₙ), temperature(tₙ) and Coulombs(tₙ) passed at various times, tₙ (n=1, 2, 3, . . . x) during the discharging
c. using a computer processor to determine an input SOC(tₙ) based on the Coulombs at time tₙ if this is the first time determining a refined SOC;
d. using the input SOC(tₙ), the Coulombs(tₙ), and the voltage(tₙ) and the temperature(tₙ) as input into a SOC refining algorithm run thorough a computer processer to determine a refined SOC(tₙ), wherein the SOC refining algorithm is chosen according to the following rules:
   i. when the input SOC(tₙ) is between about 100% and 15%, a first refining SOC algorithm is used;
   ii. when the input SOC(tₙ) is between about 5% and 0%, a second SOC refining algorithm is used; and
   iii. when the input SOC(tₙ) is between about 15% and 5%, an individually weighted combination of the first refining SOC algorithm and second SOC refining algorithm is used;
e. using the refined SOC(tₙ) as the input SOC(tₙ₊₁), the Coulombs(tₙ₊₁), the voltage(tₙ₊₁) and the temperature(tₙ₊₁) as inputs into the SOC refining algorithm run thorough the computer processer, to determine a refined SOC(tₙ₊₁), wherein the SOC refining algorithm is chosen according to the rules in step d):
f. repeating step e) as desired to determine the refined SOCs at various times tₙ.

In one arrangement, the first SOC refining algorithm is a polarization relaxation model. The first SOC refining algorithm may determine the refined SOC by fitting polarization or relaxation data and comparing resulting fit parameters to pre-populated lookup tables.

In one arrangement, the first SOC refining algorithm comprises the steps of:
a. measuring voltage(tₙ) and current(tₙ) as a function of time while the battery cell is discharging;
b. recording in a memory location the voltage(tₙ) as a function of time over periods in which the current(tₙ), expressed in terms of C-rate, is stable to within +/−0.01 C;
c. fitting, using a computer processor, the recorded voltage(tₙ) as a function of time to a pre-defined function that has three or more fit parameters;
d. extracting the fit parameters; and
e. comparing, using a computer processor, the fit parameters to a previously-populated look-up table that correlates the fit parameters to SOC values to determine the SOC.

The pre-defined function may have a single exponential term of the form:

OCV(t_{fit})=k₀+k₁e^{-t/τ}^{₁}.

The pre-defined function may have two exponential terms of the form:

OCV(t_{fit})=k₀+k₁e^{-t/τ}^{₁}+k₂e^{-t/τ}^{₂}.

The second SOC refining algorithm may be an empirical Kalman filter model of an operating battery with a number of inputs, including at least Coulomb counting, cell voltage and cell temperature.

In one arrangement, in step d), the individually weighted combination of the first refining SOC algorithm and second SOC refining algorithm is based on weighting factors from a pre-defined lookup table.

In another arrangement, in step d), the individually weighted combination of the first refining SOC algorithm and second SOC refining algorithm is given by:

w(tₙ)₁=(SOC(tₙ)−5)/10 and

w(tₙ)₂=1−w(tₙ)₁

wherein w(tₙ)₁ is a fractional weighting factor for the first refining SOC algorithm, w(tₙ)₂ is a fractional weighting factor for the second refining SOC algorithm, and SOC(tₙ) is the input SOC at time tₙ in percent.

### DETAILED DESCRIPTION

The preferred embodiments are illustrated in the context of determining SOC for Li cells that have LiFePO₄ cathodes. The skilled artisan will readily appreciate, however, that the materials and methods disclosed herein will have application with a number of other battery chemistries where determination of SOC using standard methods is difficult, particularly where accuracy and real-time measurement are important.

A method has been developed to improve the accuracy of SOC determination by employing both a physical model and an empirical model and weighting the influence of each depending on a rough approximation of the state of charge using conventional methods. The result is a hybrid model that determines accurately the SOC of a battery over its entire voltage operating range through careful application of two different models.

The embodiments of the invention as disclosed herein can be used in a wide variety of battery powered applications where maximum efficiency, high reliability, safety and maximum use of available energy are desired. Applications include, but are not limited to, electric and hybrid electric vehicles, stationary power, portable electronic devices (cell phones, laptops, tablets, PDAs), and UPS systems.

In one embodiment of the invention, a physical model is an electrochemical model, based on the battery materials properties and structure. The model describes dynamic electrochemical reactions and their corresponding impact on Lithium-ion (Li+) utilization including such things as electrode potentials, salt concentration, energy balance of the cell, and side reactions. Further details about an exemplary physical model and its algorithm, which can be used in the embodiments of the invention are described below.

In one embodiment of the invention, an empirical (or data-driven) model is a mathematical model that includes a Coulomb-counting component, a hysteresis compensation component, a relaxation filter, and an adaptive correction that uses a Kalman filter. Kalman filter modeling is well known to those of ordinary skill in the art of control systems.

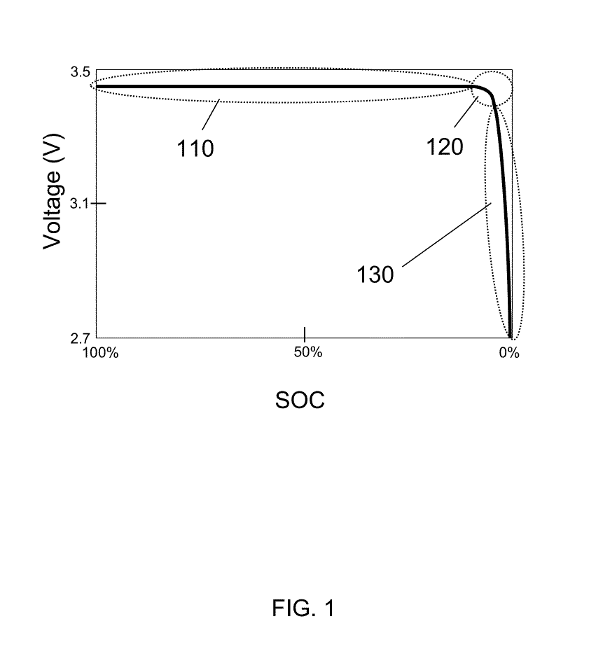

FIG. 1 is a plot of cell voltage as a function of state of charge. The curve has three distinct regions indicated as 110, 120, 130. Region 110 includes SOCs between about 100% and 15%. Region 120 includes SOCs between about 15% and 10%. Region 130 includes SOCs between about 10% and 1%. In one embodiment of the invention, the shape of the cell voltage curve is used to determine which model is favored for determining SOC. Although algorithms from both models may be running continuously, one or both algorithms may be applied at various times. For example, in region 110, the voltage curve is essentially flat, and the physical model is used. In region 130, the voltage curve is severely sloped, and the empirical model is used primarily. In region 120, the physical model and the empirical modes are used together with weighted factors that may change throughout region 120.

In one embodiment of the invention, in region 120, a blending algorithm is based on input SOC and calculates weighting factors, w for each of the data-driven and physical model estimation results. In one arrangement, the fractional weighting factor w for the physical model at time tₙ is given by:

w(tₙ)_{P}=(SOC(tₙ)−5)/10

and for the empirical model by:

w(tₙ)_{E}=1−w(tₙ)_{P}

where SOC is the input SOC in percent.

In one embodiment of the invention, data-driven model parameters are updated by using the physical model to calculate the parameters which can be converted to the format of the data-driven model based on. The SOC/SOH, thermal management and available power calculations; e.g. cell capacity, internal resistance and etc., can be updated by the physical model and used by the data-driven model for SOC/SOH, thermal calculation and available power calculations.

In another embodiment of the invention, the physical model conditions are updated by using the data-driven model to produce an accurate SOC during its active operation range. This output can be fed into the physical model as the initial conditions for continuous operation in the flat curve area 110. Long term error accumulation is avoided by this method.

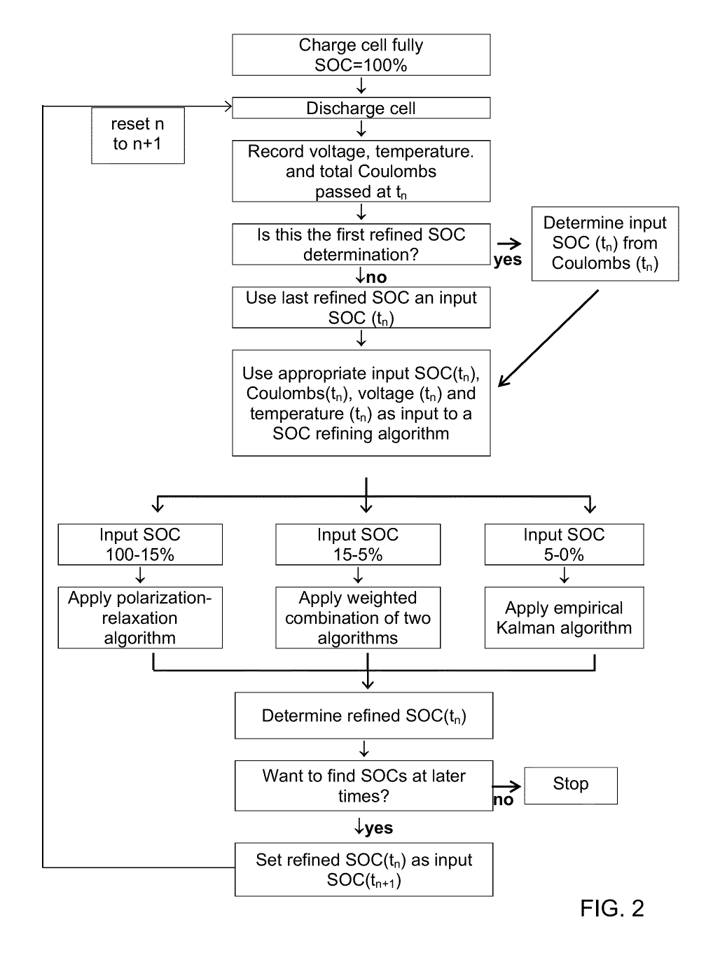

FIG. 2 is a logic diagram that outlines the steps of a process to apply the embodiments of the invention to cells in a battery pack. First a cell is charged fully so the SOC is 100%. Then the cell begins to discharge. At time tₙ, values for voltage, temperature, and total Coulombs passed are recorded. If this is the first refined determination of SOC, the input SOC at tₙ is determined from the Coulombs passed (i.e., Coulombs at full charge−Coulombs passed=SOC(tₙ)). Then the input SOC(tₙ), Coulombs(tₙ), voltage (tₙ) and temperature (tₙ) are used as input to an SOC refining algorithm.

If the input SOC(tₙ) is between 100% and 15%, the polarization-relaxation algorithm is applied. If the input SOC(tₙ) is between 5% and 0%, a weighted combination of the polarization-relaxation algorithm and the empirical Kalman algorithm is applied. If the input SOC(tₙ) is between 15% and 5%, the empirical Kalman algorithm is applied. The applied algorithm(s) are used to determine a refined SOC(tₙ). If this is to be the last SOC determination, the process stops here. If further SOC determinations are desired, n is set to n+1, and the process begins again at the cell discharge step.

Now, this is not the first refined SOC determination, so the last refined SOC(tₙ) becomes the input SOC(tₙ₊₁), and the process proceeds as discussed above.

Advantages of the embodiment of the invention, as disclosed herein include being able to use the maximum capacity of cell, battery modules and packs, without risking damage to the battery or shortening its cycle life. At the same time, thermal performance of the battery is estimated accurately for better battery pack thermal control, which aids in finding the most efficient conditions under which to operate the pack.

### A Physical/Relaxation Model

In one embodiment of the invention, a physical mode for determining SOC is the model described in pending U.S. patent application Ser. No. 13/940,176, “Relaxation Model in Real-Time Estimation if State-Of-Charge in Lithium Polymer Batteries,” which is incorporated by reference within for all purposes.

A physical model for measuring SOC and SOH based on real-time determination of physical parameters in an operating cell has been developed based on recording cell voltage over time.

Electrolyte relaxation in polarized electrochemical cells can be rigorously modeled using Equation 1.

OCV(t_{fit})=k₀+k₁e^{-t/τ}^{₁} [1]

where τ₁, k₀, and kₜ are constants, t is elapsed time and t_{fit} refers specifically to the relaxation time period over which the fit is performed. This simple framework was derived for restricted diffusion experiments, which have been made under a specific set of conditions:

cells are symmetric (having two identical electrodes in a planar configuration);
cells are well-polarized initially;
thermodynamic potential across battery terminals is zero;
cell geometry is one-dimensional;
electrolyte thickness (L) is well-known; and
OCV is monitored without applied current for a substantial period of time (tᵣₑₛₜ) such that Dtᵣₑₛₜ/L²>0.05, where D is the electrolyte salt diffusion coefficient.

Under these conditions, an electrolyte relaxation period, without any current passage, can be closely fitted to Equation 1. Equation 1 has a physical basis, as given by the expression

$$τ = \frac{{π}^{2} D}{{L}^{2}} ,$$

where D is the electrolyte salt diffusion coefficient in the electrolyte. This physical basis distinguishes this method from empirical models such as RC circuit fitting. The fitting region is bounded by the time parameters t_{fit|0} and t_{fit|final}, where t_{fit|0} is the time at the start of the fitting region and t_{fit|final} is the time at the end of the fitting region. In practice, tᵣₑₛₜ is offset by t_{fit|0} such that the first point on tᵣₑₛₜ is zero, and t_{fit|final} is the total elapsed time during the fitting region. The value of OCV at time tᵣₑₛₜ=t_{fit|0} is k₁. The value of OCV at equilibrium is k₀, which is defined as zero for symmetric electrodes, but actually has a small, non-zero value due to complication such as measurement bias, thermal noise and processing differences in electrodes. In the most rigorous applications, the onset of the fitting regime may begin after tens of seconds to tens of minutes of rest, and the fitting region may be several minutes to several hours. This method describes the physical behavior so well that it can give diffusion coefficients accurate to within 0.1%.

The rigorously-defined conditions described above are not generally thought to be applicable for determining relaxation behavior in battery systems due to a number of complications because:

electrodes are not symmetric;

thermodynamic potential across battery terminals is nonzero;

battery cell geometry may not be reducible to 1-dimension; and

batteries exhibit multiple concurrent voltage relaxation phenomena.

Further academic research has shown that the restricted diffusion technique of Equation 1 can be applied to electrolyte systems that have more than one relaxation time constant, with the general result including a distribution of time constants, as shown in Equation 2.

OCV(t_{fit})=k₀+∫ₜ_{_{fit|0}}^{t}^{_{fit|final}}e^{-Γt}f(Γ)dΓ [2]

where Γ=1/τ. In its continuous form, this is the Laplace inversion equation and applies to a distribution ranging from Γ=0 to Γ=∞. This is an ill-defined problem with infinite arbitrary solutions. However, it can be discretized (t_{fit|0}−t_{fit|final} is constrained) over a specified range of F and solved rigorously using algorithms such as Contin, maximum-entropy, or global minimization, with the end result related to the overall effect of all relaxation time constants in the system. Similar to Equation 1, k₀ is the value of OCV at equilibrium. The sum of all values of F in a discretized form of f(Γ) equals the initial voltage of the fitting region.

Equations 1 and 2 apply rigorously to model relaxation phenomena within the separator/electrolyte layer in a battery system. However, in addition to the electrolyte separator polarization/relaxation, batteries exhibit other relaxation phenomena, that include, but are not limited to, electrolyte relaxation within one or both electrodes, interfacial polarization/relaxation at one or both electrodes, relaxation of uneven distribution of electrode utilization in one or more dimensions, and internal heat generation in the cell. Equation 2 broadly captures these phenomena as well because they can be generally described as a superimposed series of exponential decays.

Equation 3, an extension of Equation 1, models transient voltage behavior in battery systems that can be described as a series of two exponentials

OCV(t_{fit})=k₀+k₁e^{-t/τ}^{₁}+k₂e^{-t/τ}^{₂} [3]

where, k₂ and τ₂ are constants. In this scenario, the constant k₀ accounts for the cell equilibrium voltage at the present value of SOC; k₁ and k₂ indicate the magnitude of two relaxation phenomena, and τ₁ and τ₂ are time constants for two relaxation phenomena. The values of k₁/k₂ and τ₁/τ₂ must be sorted by sign and magnitude in order to compare values from fits to different data sets. A person with ordinary skill in the art would know how to handle this.

Typically, batteries operate under conditions of transient loads as well as transient environmental conditions. Thus, the condition in which a cell has been well-polarized and then is allowed to relax at OCV for long periods of time may be rarely, if ever, met. These conditions are desirable for the framework described for restricted diffusion experiments, but we demonstrate that short periods of stability, either under open-circuit or load conditions, are sufficient for capturing meaningful information with this method.

### Resting Cells

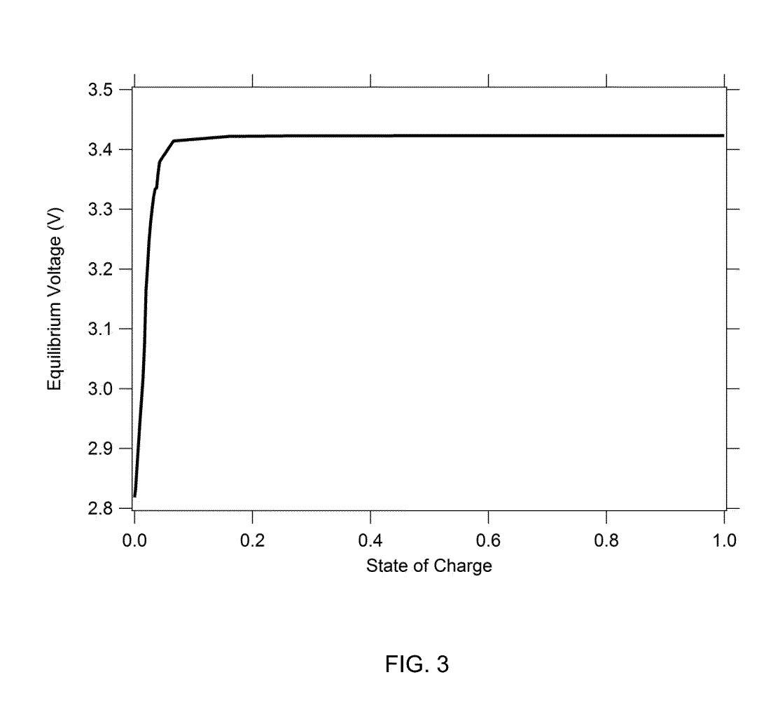

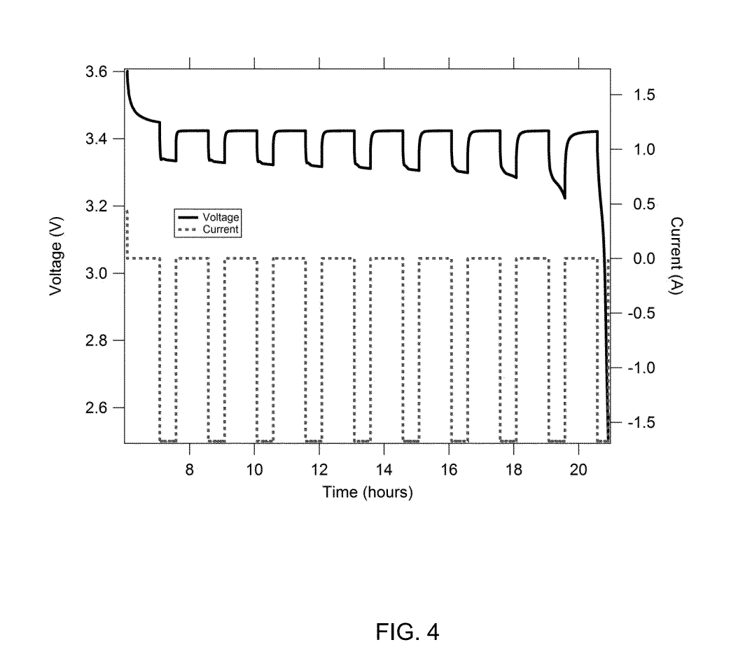

The voltage curve in FIG. 4 is from a battery cell that started from a fully-charged state and underwent a constant-current discharge for 0.5 hours. As the cell discharged, the voltage decreased from the OCV value of 3.42V to about 3.3V. In the initial region of the discharge, the cell has a flat curve of voltage vs. SOC, as shown in FIG. 3. During the periods when discharge currents are applied, the voltage decrease was caused by cell polarization processes described above. The discharge steps were stopped at increments of 10% of the total cell capacity, at which points the battery was allowed to rest for 1 hour periods. During these rest periods, the cell relaxed back towards its OCV value. The OCV values at each SOC point along the curve in FIG. 4 agree with the separately-determined OCV values in the equilibrium OCV vs SOC curve in FIG. 3.

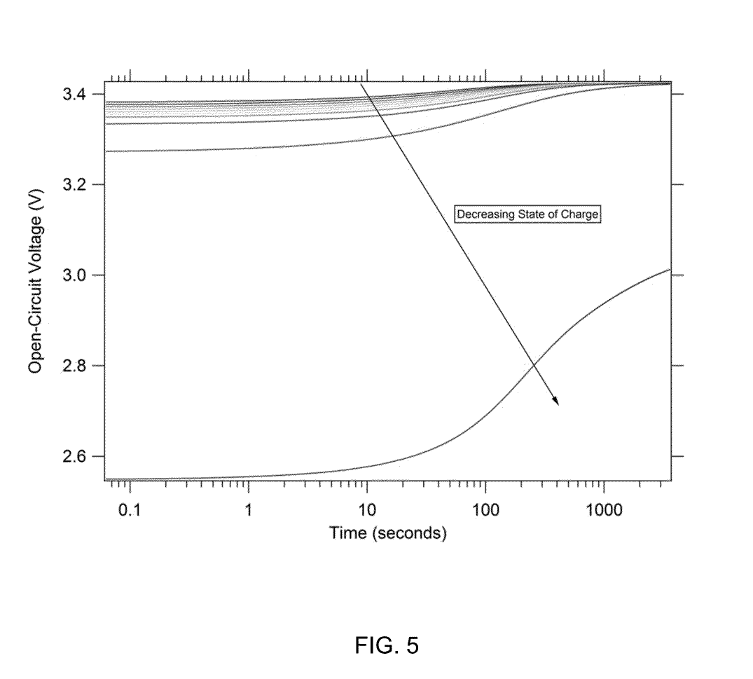

Data was extracted from the curve in FIG. 4, resulting in the OCV vs. time curves in FIG. 5. Each curve in FIG. 5 was individually fitted to a discretized form of Equation 2 using the Contin algorithm. The output of this fitting routine is the distribution function of time constants, f(Γ), along the range of 10⁻⁴ s<Γ<0.1 s. The distribution functions capture the relative contribution of relaxation time constants observed during the course of the OCV measurement. The distribution functions fit the curves in FIG. 5 closely across the entire time-scale and are not shown for clarity.

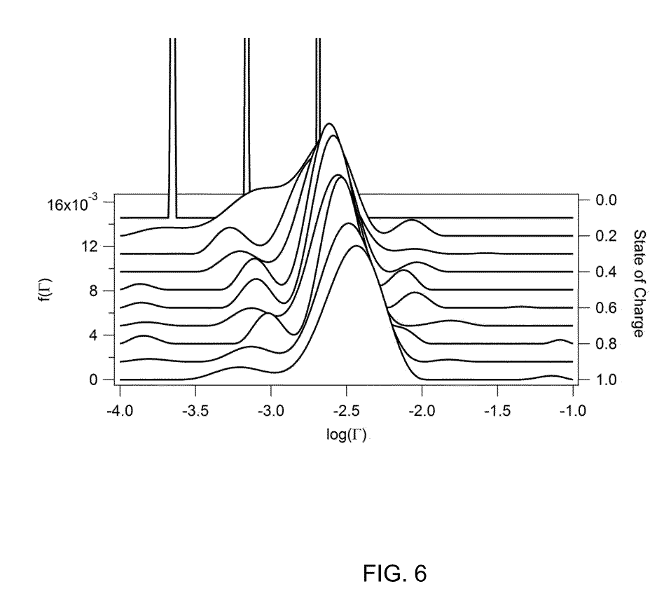

FIG. 6 is a series of relaxation curves that show distributions for f(Γ) for various SOCs. At each value of SOC, the relaxation curve has a unique fingerprint associated with it. The curves tend to have peaks that are relatively well-separated, making it possible to distinguish multiple concurrent relaxation processes. Concurrent relaxation processes that share the same value of F would appear as a relatively larger contribution to f(Γ). Concurrent relaxation processes that manifest as distributions of time constants and overlap in their range of F would appear as overlapping peaks. Because the time scale in FIG. 6 covers orders of magnitude, distinctly separated peaks must arise from distinct relaxation processes. The values of F in FIG. 6 are physically relevant to the physical and geometric properties of the battery system under study, with some timescales extending into hours. The fit function f(Γ) can, in principle, be estimated with information gained at much shorter timescales as long as the data is obtained with sufficient resolution. Thus, the relaxation time constants can be captured within tens of seconds, rather than minutes or hours. Although the characteristic fingerprints of f(Γ) change noticeably from 100 to 20% SOC, the curves at 10% and 0% SOC change dramatically, indicating a very strong signal in that regime.

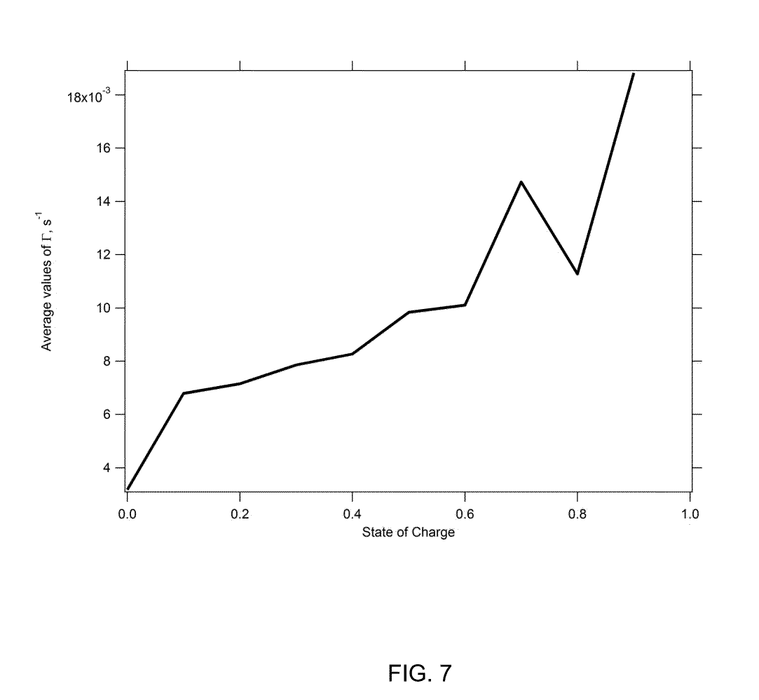

The distribution functions in FIG. 6 are clearly distinct. The distributions in FIG. 6 can be analyzed in numerous ways, including, but not limited to, finding peak centers, peak widths, and deconvolving overlapping peaks. A simple method of averaging the distributions in FIG. 6 was chosen. FIG. 7 is a plot of average time constants Γ_{average} from the distributions in FIG. 6 as a function of SOC, calculated using Equation 4.

$${Γ}_{average} = \frac{{Σ}_{i} f ( {Γ}_{i} ) {Γ}_{i}}{{Σ}_{i} f ( {Γ}_{i} )} \qquad [ 4 ]$$

where Γᵢ values are the discrete components of the fitted distribution function. Equation 3 is equivalent to the 1^{st}/0^{th} moments of the distribution, and calculating Γ_{average} in this manner weights the average by the magnitude of the contribution at each value of F. This calculation captures the average relaxation behavior across the entire fitted range. On average, the time constants decrease as the cell discharges more deeply, with the steepest slope at the deepest discharge states. The data in FIGS. 1 through 4 show that a cell's relaxation curve can provide information related to its SOC, thus validating this method.

The experiment whose results are shown in FIG. 4 was designed to capture relaxation curves at various values of SOC. Those curves were individually extracted as shown in FIG. 5 and fitted using Equation 2. The fit results gave distribution functions that indicated that the cell had unique relaxation behavior at each value of SOC, but the distribution functions were difficult to correlate directly to SOC.

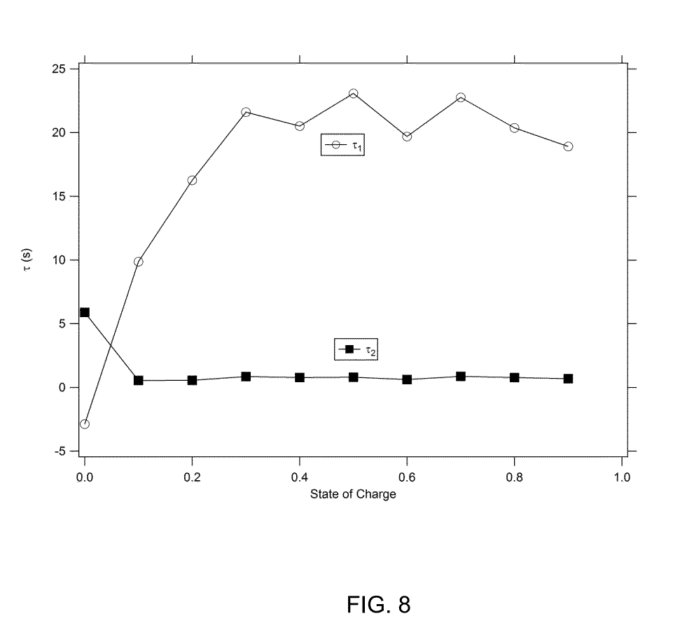

Detailed distribution function fitting and analysis, as described in the generation of FIGS. 3 and 4, requires long relaxation times and intensive computational power. This method may be difficult to implement efficiently with current embedded computer hardware and with realistic real-world rest periods. But a simple approach was found. The first 10s of the relaxation curves in FIG. 5 were fit with a double-exponential decay, using an implementation of the Levenberg-Marquardt algorithm, in order to extract the relaxation time constants τ₁ and τ₂. FIG. 8 shows a plot of the relaxation time constants as a function of SOC. In FIG. 8, τ₂ has a small value that remains relatively constant across the cell's DOD range. Without wishing to be bound to any particular theory, it may be that τ₁ corresponds to the initial depolarization of the electrochemical interfaces within the cell. In FIG. 8, τ₁ is also relatively small compared to the relaxation processes that are detected during long rest steps, but it provides a value that is sensitive (i.e., has a steep slope) to the cell's SOC at deep discharge states. Thus, such a simple fitting algorithm and a rest period on the order of seconds may be sufficient to detect useful information about a cell's changing SOC as the cell cycles. It is not only feasible to include such short rest periods in real-world battery cell operating conditions, but there are many operating scenarios where such short rest periods occur during normal operation.

### Resting Cells

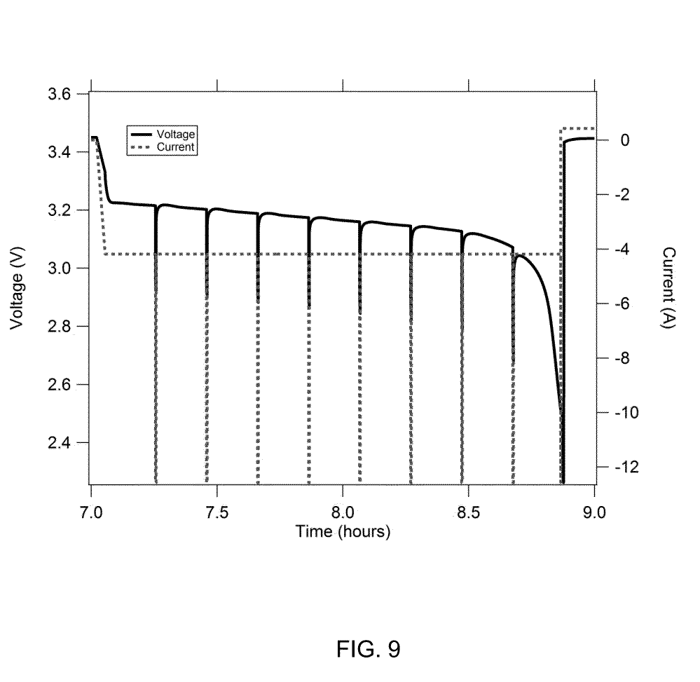

The preceding discussion has been for scenarios in which short rest periods can be incorporated into the cycling of a cell. But, it would be even more useful to find a way to determine SOC without rest periods. For example, an electric car battery has a long duty cycle during a road trip, and it is important to monitor the battery's SOC at various times during that trip. During city driving, there are many opportunities for rest periods, such as at stoplights. But on a long road trip, a car may run for hours without stopping at all. Introducing rest periods into a long road trip would not be at all desirable. However, there are nearly constant changes in the load even during such a trip. For example, the load on the battery increases when accelerating or when going up a hill. A hypothetical example of such a duty cycle is shown in FIG. 9 in a plot of voltage as a function of time. In FIG. 9, a cell undergoes a steady discharge with periodic high-current spikes whenever its capacity is reduced by about 10%. For a continuously discharging cell, each change in the applied current results in increased (decreased) polarization of the cell when the current increases (decreases).

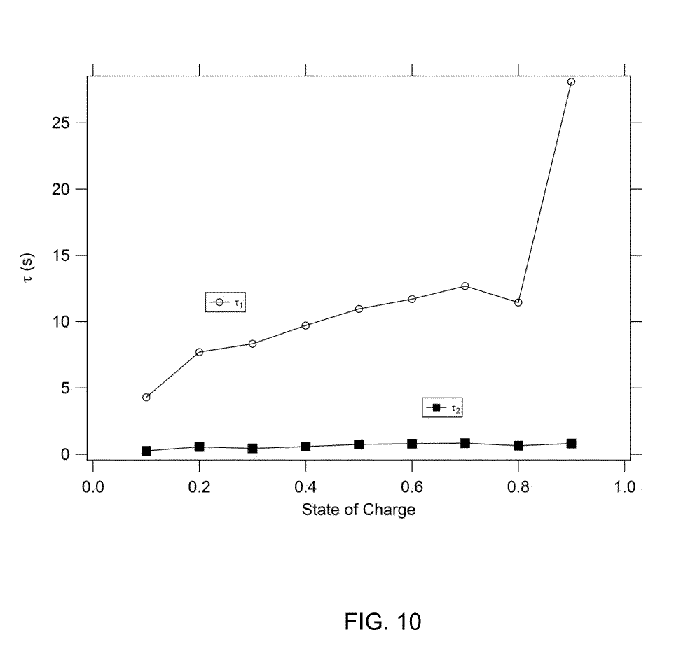

With the same double-exponential fit used to generate FIG. 8, voltage depolarization curves were fit to the first 10s after the current returned to the baseline value around negative 4 Amps. There is no fully discharged state here because, at the end of the final pulse, the cell returns to a rest state rather than a lower discharge state. The resulting time constants are shown in FIG. 10.

The first 10 seconds after the current returned to the baseline values of the curves in FIG. 9 were fit with a double-exponential decay, using an implementation of the Levenberg-Marquardt algorithm, as was described above for FIG. 7. There is no fully discharged state here because, at the end of the final pulse, the cell returns to a rest state rather than a lower discharge state. FIG. 10 shows a plot of the relaxation time constants as a function of SOC. In FIG. 10, τ₂ has a very small value that remains relatively constant across the cell's SOC range. In FIG. 8, τ₁ is also relatively small compared to the relaxation processes that are detected during long rest steps, but it provides a value that is sensitive (i.e., has a steep slope) to the cell's SOC at many discharge states. Thus, such a simple fitting algorithm can also be used to determine SOC even without rest periods.

This example used a current with a magnitude of 4 Amps for a cell with a capacity of approximately 8 Amp-hours. Charge and discharge rates are routinely expressed relative to the rate at which a cell would be fully charged or discharged in a period of 1 hour. The term for this ratio is C-rate, and is typically expressed as C. Thus, for an 8 Amp-hour cell, a charge or discharge current of 8 Amps would be 1 C. In the example above, the 4 Amp discharge corresponds to C/2. In principle, this method would apply at much lower C-rates.

These results show that τ₁ has a relatively strong dependency on SOC. Interestingly, this τ₁ is most sensitive to SOC near the fully charged state—just the opposite of the dependency of the τ₁ in the rest case (FIG. 8), which is most sensitive to SOC near the fully discharged state. Furthermore, the τ₁ in FIG. 10 is more sensitive across the entire SOC range than the τ₁ in FIG. 8, suggesting that dynamic usage scenario can give even more useful SOC information. The magnitudes of the time constants are similar in FIGS. 5 and 7, which suggests that the same physical relaxation processes are at work in each usage scenario (depolarizing from a load state to a rest state versus depolarizing from a high-load state to a lower-load state).

The curves of time constants vs. SOC shown in FIGS. 5 and 7 would serve as a database for future analysis of relaxation data. These experiments, and others in which controlled charge or discharge sequences are performed, could be used to populate one or more tables of data. This data would be stored and referenced upon command. For example, if this fitting method were performed in real time on an operating cell, the resultant fit parameters could be compared to stored, previously-generated data in order to get an estimate of the cell's SOC. It is logical to assume that transient voltage responses under load would give different fit results depending on the current sign and magnitude. Thus, there is additional value in having richly-populated tables in which numerous experimental conditions were tested, fitted and analyzed prior to a cell's installation for long-term usage. Furthermore, the cell response behavior may change over the course of the cell's lifetime as aging and other effects occur. To that end, the database may be periodically replenished. For example, the initial experiments used to build the database could be repeated periodically as a cell ages.

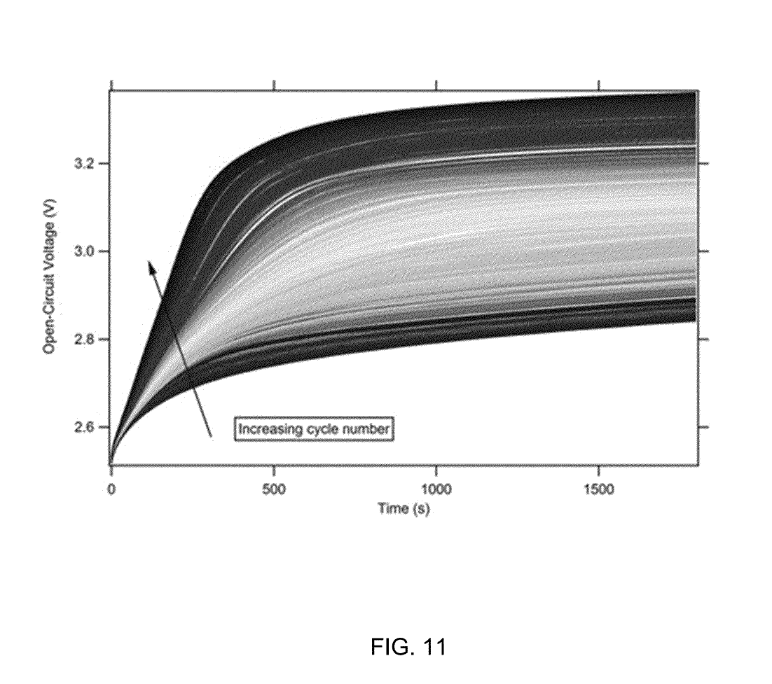

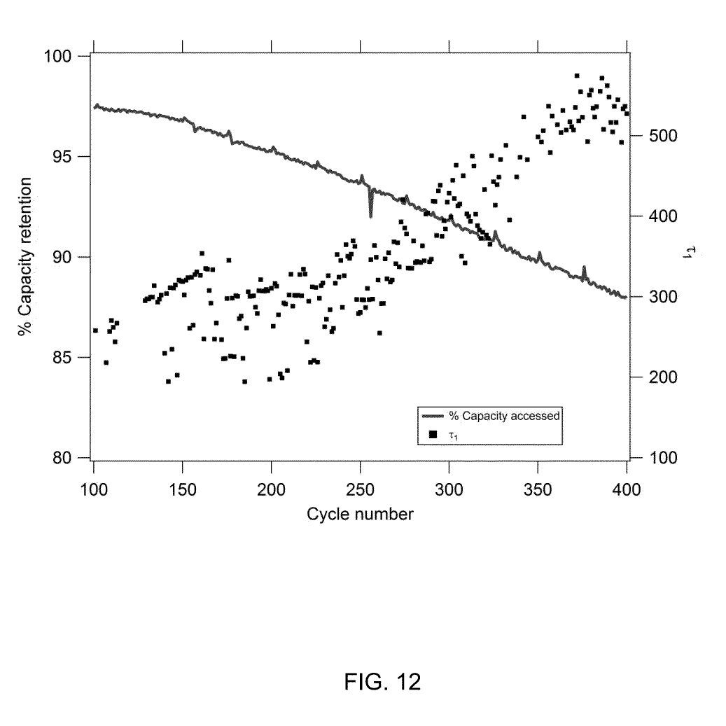

The relaxation processes that indicate a cell's state-of-charge are sensitive to the processes happening in the cell's active material—these processes may be occurring either within active particles, at active particle surfaces, or between active particles in a composite electrode. The physical and chemical characteristics that give rise to these processes may change over the lifetime of a cell due to chemical reactions, physical redistribution of materials, etc. Thus one would expect that relaxation time constants for these processes would change as a cell ages due to changes in transport properties, impedances, diffusion barriers and length-scales. FIG. 11 shows relaxation curves following nearly 500 deep-discharge cycles for a battery. The shape of the relaxation curves changes substantially over this number of cycles, with the relaxation proceeding progressively faster at the later cycle numbers. Relaxation time constants for fits to the first 100 seconds of each curve are shown in FIG. 12.

The time constants in FIG. 12 show sensitivity of the time constants to the capacity fade process happening in the first 50 cycles (the capacity access dips, and the time constants show an inverse peak). The time constants also show sensitivity to the slower capacity fade process happening between 100-400 cycles. In this region, the larger time constants increase from around 200 to around 500 seconds.

These time constants can be tracked at the end of every duty cycle while the battery rests before charging. Given the results described above for battery SOC monitoring via time constant determination, it is likely that SOH information could be determined under a variety of scenarios, including changing load scenarios.

### Using a Computer Processor

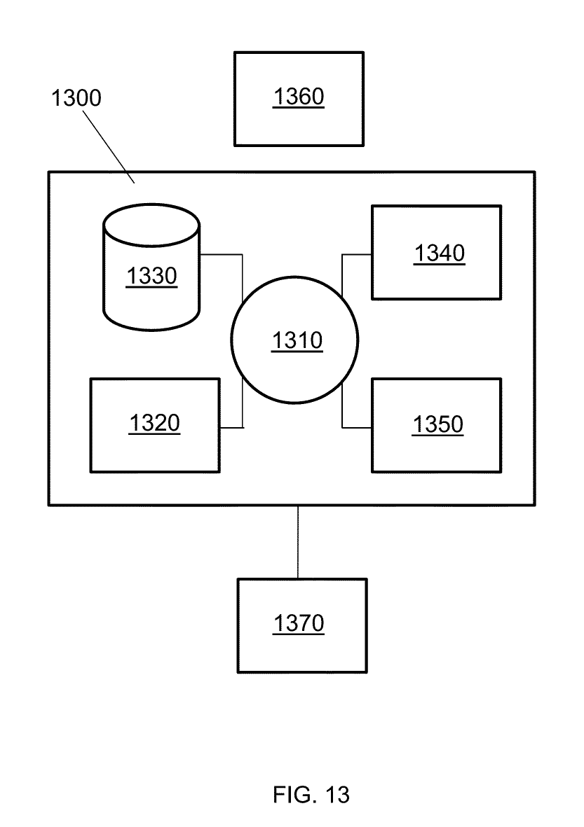

Methods of the present disclosure, including applications of algorithms for determining battery state of charge, can be implemented with the aid of computer systems. FIG. 13 shows a computer system 1300 that is programmed or otherwise configured to determine the state of charge of a battery. The system 1300 includes a central processing unit (CPU, also “processor” and “computer processor” herein) 1310, which can be a single core or multi core processor, or a plurality of processors for parallel processing. The system 1300 also includes computer memory 1320 (e.g., random-access memory, read-only memory, flash memory), electronic data storage unit 1330 (e.g., hard disk), communication interface 1340 (e.g., network adapter) for communicating with one or more other systems and/or components (e.g., batteries), and peripheral devices 1350, such as cache, other memory, data storage and/or electronic display adapters. The memory (or memory location) 1320, storage unit 1330, interface 1340 and peripheral devices 1350 are in communication with the CPU 1310 through a communication bus (solid lines), such as a motherboard. The storage unit 1330 can be a data storage unit (or data repository) for storing data.

In some situations, the computer system 1300 includes a single computer system. In other situations, the computer system 1300 includes multiple computer systems in communication with one another, such as by direct connection or through an intranet and/or the Internet.

Methods as described herein can be implemented by way of machine (or computer processor) executable code (or software) stored on an electronic storage location of the system 1300, such as, for example, on the memory 1320 or electronic storage unit 1330. During use, the code can be executed by the processor 1310. In some cases, the code can be retrieved from the storage unit 1330 and stored on the memory 1320 for ready access by the processor 1310. As an alternative, the electronic storage unit 1330 can be precluded, and machine-executable instructions can be stored in memory 1320. The code can be pre-compiled and configured for use with a machine have a processer adapted to execute the code, or can be compiled during runtime. The code can be supplied in a programming language that can be selected to enable the code to execute in a pre-compiled or as-compiled fashion.

The system 1300 can include or be coupled to an electronic display 1360 for displaying the state of charge and/or refined state of charge of one or more batteries. The electronic display can be configured to provide a user interface for providing the state of charge and/or refined state of charge of the one or more batteries. An example of a user interface is a graphical user interface. As an alternative, the system 1300 can include or be coupled to an indicator for providing the state of charge and/or state of health of one or more batteries, such as a visual indicator. A visual indicator can include a lighting device or a plurality of lighting devices, such as a light emitting diode, or other visual indicator that displays the state of charge or refined state of charge of a battery (e.g., 10%, 20%, 30%, 40%, 50%, 60%, 70%, 80%, or 90% of maximum charge). Another example of an indicator is an audible indicator or a combination of visual and audible indicators.

The system 1300 can be coupled to one or more batteries 1370. The system 1300 can execute machine executable code to implement any of the methods provided herein for determining the state of charge of the one or more batteries 1370.

Aspects of the methods and systems provided herein, such as methods for determining the state of charge of a battery, can be embodied in programming. Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

This invention has been described herein in considerable detail to provide those skilled in the art with information relevant to apply the novel principles and to construct and use such specialized components as are required. However, it is to be understood that the invention can be carried out by different equipment, materials and devices, and that various modifications, both as to the equipment and operating procedures, can be accomplished without departing from the scope of the invention itself.

We claim:

1. A method of determining state of charge (SOC) for a rechargeable battery cell at various times tₙ throughout the discharge portion the cell's cycle comprising the steps of:
a) fully charging a battery cell comprising lithium metal as an anode, lithium iron phosphate as a cathode, and a polymer electrolyte as a separator so that SOC is 100%;
b) discharging the cell over a period of time tₓ while also recording in a memory location voltage(tₙ), temperature(tₙ) and Coulombs(tₙ) passed at various times, tₙ (n=1, 2, 3, . . . x) during the discharging
c) using a computer processor to determine an input SOC(tₙ) based on the Coulombs at time tₙ if this is the first time determining a refined SOC;
d) using the input SOC(tₙ), the Coulombs(tₙ), and the voltage(tₙ) and the temperature(tₙ) as input into a SOC refining algorithm run thorough a computer processer to determine a refined SOC(tₙ), wherein the SOC refining algorithm is chosen according to the following rules:
i. when the input SOC(tₙ) is between about 100% and 15%, a first refining SOC algorithm is used;
ii. when the input SOC(tₙ) is between about 5% and 0%, a second SOC refining algorithm is used; and
iii. when the input SOC(tₙ) is between about 15% and 5%, an individually weighted combination of the first refining SOC algorithm and second SOC refining algorithm is used;
e) using the refined SOC(tₙ) as the input SOC(tₙ₊₁), the Coulombs(tₙ₊₁), the voltage(tₙ₊₁) and the temperature(tₙ₊₁) as inputs into the SOC refining algorithm run thorough the computer processer, to determine a refined SOC(tₙ₊₁), wherein the SOC refining algorithm is chosen according to the rules in step d):
f) repeating step e) as desired to determine the refined SOCs at various times tₙ.

2. The method of claim 1 wherein the first SOC refining algorithm comprises a polarization relaxation model.

3. The method of claim 2 wherein the first SOC refining algorithm determines SOC by fitting polarization or relaxation data and comparing resulting fit parameters to pre-populated lookup tables.

4. The method of claim 3 wherein the first SOC refining algorithm comprises the steps of:
a. measuring voltage(tₙ) and current(tₙ) as a function of time while the battery cell is discharging;
b. recording in a memory location the voltage(tₙ) as a function of time over periods in which the current(tₙ), expressed in terms of C-rate, is stable to within +/−0.01 C;
c. fitting, using a computer processor, the recorded voltage(tₙ) as a function of time to a pre-defined function that has three or more fit parameters;
d. extracting the fit parameters; and
e. comparing, using a computer processor, the fit parameters to a previously-populated look-up table that correlates the fit parameters to SOC values to determine the SOC.

5. The method of claim 4 wherein the pre-defined function has a single exponential term of the form. OCV(t_{fit})=k₀+k₁e^{-t/τ}^{₁}.

6. The method of claim 4 wherein the pre-defined function has two exponential terms of the form: OCV(t_{fit})=k₀+k₁e^{-t/τ}^{₁}+k₂e^{-t/τ}^{₂}.

7. The method of claim 1 wherein the second SOC refining algorithm comprises an empirical Kalman filter model of an operating battery and a number of inputs, including at least Coulomb counting, cell voltage and cell temperature.

8. The method of claim 1 wherein, in step d), the individually weighted combination of the first refining SOC algorithm and second SOC refining algorithm is based on weighting factors from a pre-defined lookup table.

9. The method of claim 1 wherein, in step d), the individually weighted combination of the first refining SOC algorithm and second SOC refining algorithm is given by:
w(tₙ)₁=(SOC(tₙ)−5)/10 and
w(tₙ)₂=1−w(tₙ)₁
wherein w(tₙ)₁ is a fractional weighting factor for the first refining SOC algorithm, w(tₙ)₂ is a fractional weighting factor for the second refining SOC algorithm, and SOC(tₙ) is the input SOC at time tₙ in percent.
